(19) United States
(12) Patent Application Publication
(10) Pub. No.: US 2024/0118331 A1
(43) Pub. Date: Apr. 11, 2024

(54) METHOD FOR EVALUATING A TRANSMISSION LINE THROUGH AUTOMATIC ANALYSIS OF A REFLECTOGRAM

(71) Applicant: COMMISSARIAT A L’ENERGIE ATOMIQUE ET AUX ENERGIES ALTERNATIVES, Paris (FR)

(72) Inventors: Nicolas RAVOT, GIF-SUR-YVETTE (FR); Baudouin NALINE, GIF-SUR-YVETTE (FR); Pierre BLANCHART, GIF-SUR-YVETTE (FR); Nicolas GREGIS, GIF-SUR-YVETTE (FR)

(21) Appl. No.: 18/376,097

(22) Filed: Oct. 3, 2023

(30) Foreign Application Priority Data
Oct. 3, 2022 (FR) 2210081

(51) Int. Cl. G01R 31/08; G01R 31/11

(52) U.S. Cl. CPC G01R 31/088; G01R 31/085; G01R 31/11

(57) ABSTRACT

A novel method for automatically analyzing reflectograms in order to classify impedance discontinuities detected via their temporal or spectral signatures into various categories relating to potential faults or other physical elements present on the cable. A method for detecting the mutual influence of neighboring pulses in a reflectogram in order to separate them so as to isolate them and characterize each pulse accurately.

### CROSS-REFERENCE TO RELATED APPLICATION

This application claims priority to foreign French patent application No. FR 2210081, filed on Oct. 3, 2022, the disclosure of which is incorporated by reference in its entirety.

### FIELD OF THE INVENTION

The invention relates to the field of systems and methods for diagnosing the state of health of a cable or, more generally, of a transmission line. It falls within the field of reflectometry-based diagnostic methods that aim to detect and locate electrical faults on a cable or on a network of cables.

### BACKGROUND

The invention relates more specifically to a method for evaluating impedance discontinuities on a transmission line through automated analysis of a reflectogram.

The invention is applicable to any type of electrical cable, in particular power transmission cables or communication cables, in fixed or mobile installations. The cables in question may be coaxial, bifilar, parallel lines, twisted pairs, cable strands or the like. The invention may also be applicable to mechanical cables, for example cables supporting infrastructures such as an elevator or a bridge.

Transmission lines may be exposed to stressful internal and external conditions that are both natural and artificial disturbances, such as temperature fluctuations, humidity, pressure, etc., thus leading to the appearance of anomalies, which are often called faults. These faults may be located at one point in the case of open circuits or short circuits (hard faults). The faults may also result from surface damage to the cable, and reference is then made to soft faults.

In recent decades, considerable effort has been invested in research and industry to study and develop techniques capable of detecting the presence, the location and the characteristics of cabling faults that could jeopardize the infrastructures that depend on these networks. As a result, fault monitoring and cable troubleshooting have become a significant issue in order to guarantee safe operation, high performance and optimum profitability.

One of the known techniques for detecting and locating the presence of a fault is the technique known as reflectometry.

In accordance with a known principle, what are known as reflectometry methods are used to detect and/or locate electrical or mechanical faults that cause impedance discontinuities or breaks in a cable.

These methods use a principle close to that of radar: an electrical signal, often a high-frequency or wideband electrical signal, is injected at one or more locations of the cable to be tested. The signal propagates through the cable or the network and returns some of its energy when it encounters an electrical discontinuity. An electrical discontinuity may result for example from a connection, from the end of the cable or more generally from a break in the conditions of propagation of the signal in the cable. It results more often than not from a fault that locally modifies the characteristic impedance of the cable by causing a discontinuity in its linear parameters, which may ultimately result in a severe failure caused by the appearance of a hard fault.

Analyzing the signals returned to the point of injection makes it possible to deduce therefrom information about the presence and the location of these discontinuities, and therefore potential faults. Analysis in the time or frequency domain is usually carried out. These methods are denoted by the acronyms TDR, from the expression “time domain reflectometry”, and FDR, from the expression “frequency domain reflectometry”.

The analysis is carried out using a reflectogram, which gives the impulse response of the signal measured after backpropagation thereof in the cable. This reflectogram comprises various pulses or amplitude peaks that are characteristic of impedance discontinuities in the cable. The analysis of the reflectogram in order to detect and locate potential faults on the cable is generally carried out through a subjective interpretation performed by an expert in the field, who is capable of identifying the temporal or spectral signature of a fault on the reflectogram.

However, a person who is not an expert will not necessarily be able to correctly interpret a reflectogram in order to provide a diagnosis on the state of health of the cable. There is therefore a need for a method for automatically analyzing and interpreting a reflectogram with a view to providing a diagnosis.

There are methods for automatically analyzing signals in remote technical fields such as the medical field or imaging-based pattern recognition.

For example, reference [1] relates to the application of neural networks to recognize and classify waves and anomalies in an ECG electrocardiographic signal. Article [2] proposes a method for automatically detecting peaks on noisy signals. Document [3] aims to design new techniques for representing signals and to ensure that these techniques enhance the ability of a passive sonar system to recognize and interpret the signals received by the antenna placed upstream of the system.

However, none of these documents relates to the field of diagnosing the state of health of cables and automatically analyzing reflectograms.

### SUMMARY OF THE INVENTION

The invention proposes a novel method for automatically analyzing reflectograms in order to classify impedance discontinuities detected via their temporal or spectral signatures into various categories relating to potential faults or other physical elements present on the cable.

The invention is based notably on a method for detecting the mutual influence of neighboring pulses in a reflectogram in order to separate them so as to isolate them and characterize each pulse accurately.

One subject of the invention is a method for evaluating a transmission line through reflectometry, comprising the following steps:
Obtaining a measurement of the temporal impulse response of a reference signal propagated in the line from a point of injection and then backpropagated to a point of measurement, the temporal measurement, called a reflectogram, comprising a plurality of amplitude peaks each corresponding to an impedance discontinuity,
Searching for a set of local extrema in the reflectogram,
Determining a total reconstruction of the reflectogram as the sum of pulses each having the shape of the reference signal and the position and the amplitude of said local extrema,
For each pair of successive local extrema of indices j and j+1, comparing the total reconstruction with, respectively, a first partial reconstruction of the reflectogram for the local extrema of indices 0 to j and a second partial reconstruction of the reflectogram for the local extrema of indices j+1 to N−1, N being the number of local extrema, to determine whether or not the pulses of indices j and j+1 of the reflectogram have a mutual influence on one another,
For a group of pulses of the reflectogram that have a mutual influence on one another, determining an optimized reconstruction of the group of pulses from a partial reconstruction of the pulses of the group so as to modify the abscissas of the pulses of the partial reconstruction in order to minimize an error criterion between the optimized partial reconstruction and the measured reflectogram,
Comparing the difference between the optimized partial reconstruction and the measured reflectogram with a first error threshold and, if the difference is less than the first error threshold, classifying the impedance discontinuity associated with each pulse of the group of pulses according to its position and its amplitude into the following classes: a soft fault, a short circuit, an open circuit, a load matched to the load of the transmission line, an impedance mismatch between the measurement port and the transmission line.

According to one particular aspect of the invention, the shape of the reference signal is a Gaussian pulse.

According to one particular aspect of the invention, the step of determining whether or not the pulses of indices j and j+1 of the reflectogram have a mutual influence on one another comprises the following sub-steps:
Comparing a first difference between the first partial reconstruction and the total reconstruction with a second error threshold,
Comparing a second difference between the second partial reconstruction and the total reconstruction with the second error threshold,
If at least one of the differences out of the first difference or the second difference is greater than the second error threshold, deducing therefrom that the pulses of indices j and j+1 of the reflectogram have a mutual influence on one another, otherwise deducing therefrom that they are independent.

In one particular embodiment, the method according to the invention comprises the following step:
For pulses of the reflectogram that are identified as independent, comparing the difference between the reflectogram and the total reconstruction, in a time window surrounding the pulse, with a third error threshold,
If the difference is less than the third error threshold, classifying (306) the impedance mismatch corresponding to the pulse according to its position and its amplitude into the following classes: a short circuit, an open circuit, a load matched to the load of the transmission line, an impedance mismatch between the measurement port and the transmission line.

According to one particular aspect of the invention, the optimized reconstruction is obtained by way of a trust region reflective algorithm.

In one particular embodiment, the method according to the invention comprises the following step: if the difference between the optimized partial reconstruction and the measured reflectogram is less than the first error threshold for two successive pulses, determining whether the two pulses are of substantially identical amplitudes and of opposing signs and, if so, classifying the impedance mismatch corresponding to these two pulses as resulting from a soft fault, and if not, classifying the impedance mismatch corresponding to each of the two pulses according to its position and its amplitude into the following classes: a short circuit, an open circuit, a load matched to the load of the transmission line, an impedance mismatch between the measurement port and the transmission line.

In one particular embodiment, the method according to the invention furthermore comprises the following step: a step of extracting each pulse associated with an extremum of the reflectogram, within a time interval of width chosen such that the distance between the apex of the pulse and said width is equal to a predetermined percentage, for example at least equal to 80%, of the total height of the pulse.

According to one particular aspect of the invention, the measured reflectogram is amplitude-normalized between −1 and 1.

According to one particular aspect of the invention, before the comparison with the first error threshold or the third error threshold, the reflectogram and the optimized or total partial reconstruction are normalized with respect to the extremum of the reflectogram.

In one particular embodiment, the method according to the invention furthermore comprises a step of determining the positions of the impedance discontinuities from the temporal abscissas of the extrema of the reflectogram and a step of displaying the positions and types of the impedance discontinuities on a human-machine interface.

Another subject of the invention is a computer program comprising instructions for carrying out the method according to the invention when the program is executed by a processor.

Another subject of the invention is a processor-readable recording medium on which there is recorded a program comprising instructions for carrying out the method according to the invention when the program is executed by a processor.

### BRIEF DESCRIPTION OF THE DRAWINGS

Other features and advantages of the present invention will become more clearly apparent on reading the following description with reference to the following appended drawings.

FIG. 1a shows a diagram of a first example of a time domain reflectometry system,

FIG. 1b shows a diagram of a second example of a time domain reflectometry system,

FIG. 2 shows one example of a reflectogram obtained with the reflectometry system of FIGS. 1a or 1b for a single cable,

FIG. 3 shows a flowchart detailing the steps for implementing a method for automatically analyzing a reflectogram according to one embodiment of the invention,

FIG. 4 shows one example of a time domain reflectogram,

FIG. 5 shows an illustration of a step of searching for analysis zones on the reflectogram of FIG. 4,

FIG. 6 shows an illustration of two combined pulses on the reflectogram of FIG. 4,

FIG. 7 shows one example of a total reconstruction obtained according to a step of the method that is the subject of the invention and a comparison with the reflectogram,

FIG. 8 shows a flowchart illustrating a step of analyzing a potential combination of two successive peaks of the reflectogram,

FIG. 9 shows one example of a partial reconstruction obtained according to a step of the method that is the subject of the invention and a comparison with the reflectogram,

FIG. 10 shows an illustration of one example of the mutual influence of multiple successive peaks of a reflectogram.

### DETAILED DESCRIPTION

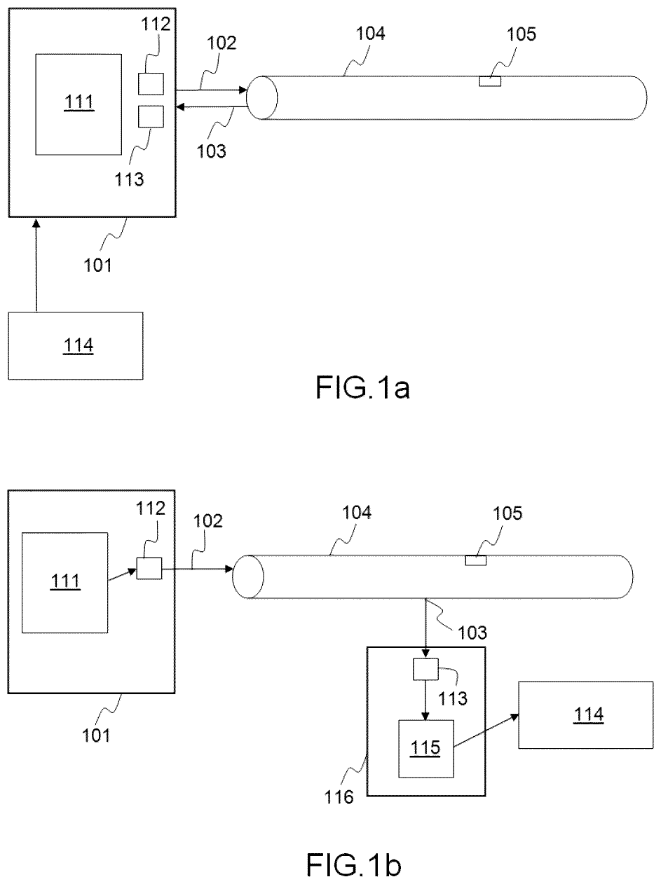

FIG. 1a depicts an overview of one example of a time domain reflectometry system. The invention lies in the context of reflectometry methods for detecting, locating or characterizing faults impacting a cable or, more generally, a transmission line.

FIG. 1a shows a cable 104 to be tested, which exhibits a fault 105 at an arbitrary distance from one end of the cable. Without departing from the scope of the invention, the cable 104 may be replaced with a network of mutually interconnected complex cables. The single cable 104 of FIG. 1a is shown for purely illustrative purposes in order to explain the general principle of a reflectometry method.

A reflectometry system 101 according to the invention comprises an integrated circuit-type electronic component 111, such as a programmable logic circuit, for example an FPGA or microcontroller, designed to carry out two functions. On the one hand, the component 111 makes it possible to generate a reflectometry signal s(t) to be injected into the cable 104 under test. This digitally generated signal is then converted via a digital-to-analog converter 112 and then injected 102 at one end of the cable. The signal s(t) propagates in the cable and is reflected from the singularity caused by the fault 105. The reflected signal is backpropagated to the point of injection and then captured 103, converted to digital via an analog-to-digital converter 113, and transmitted to the component 111. The electronic component 111 is furthermore designed to carry out the steps of the method according to the invention that will be described hereinafter in order to determine a reflectogram or multiple reflectograms from the received signal r(t).

The one or more reflectograms may be transmitted to a processing unit 114, such as a computer, personal digital assistant or the like, in order to display the results of the measurements on a human-machine interface.

The system 101 described in FIG. 1a is one exemplary embodiment that is in no way limiting. In particular, the two functions carried out by the component 111 may be separated into two separate components or devices, as illustrated in the example of FIG. 1b. The point of injection and the point of measurement of the signal may also be taken at any locations of the cable, and not at its end.

FIG. 1b shows a first device 101 dedicated to generating the reflectometry signal and injecting it into the cable, and a second device 116 dedicated to measuring the signal at any point of the cable and then computing the reflectogram via a component 115.

The component 115 may be an electronic component of integrated circuit type, such as a programmable logic circuit, for example an FPGA or a microcontroller, for example a digital signal processor, which receives the signal measurements and is configured to carry out the method according to the invention. The component 115 comprises at least one memory for saving the last signal samples generated and injected into the cable and the last measured signal samples.

As is known in the field of time domain reflectometry-based diagnostic methods, the position d_{DF} of a fault 105 on the cable 104, in other words its distance to the point of injection of the signal, may be obtained directly from the measurement, on the computed time domain reflectogram R(t), of the duration t_{DF} between the first amplitude peak recorded on the reflectogram and the amplitude peak corresponding to the signature of the fault.

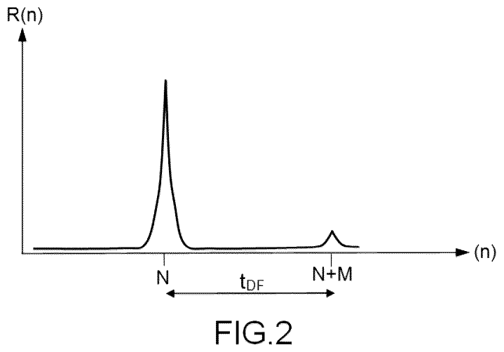

FIG. 2 shows one example of a reflectogram R(n) obtained using the system of FIG. 1a or 1b, on which it is possible to see a first amplitude peak at an abscissa N and a second amplitude peak at an abscissa N+M. The first amplitude peak corresponds to the signal injected at the point of injection into the cable, while the second peak corresponds to the reflection of the signal from an impedance discontinuity caused by a fault.

Various known methods are conceivable for determining the position d_{DF} (distance of the end of cable peak or of the hard fault). A first method consists in applying the relationship linking distance and time: d_{DF}=V_{g}·t_{DF}/2, where V_{g} is the propagation speed of the signal in the cable. Another possible method consists in applying a proportionality relationship of the type d_{DF}/t_{DF}=L_{c}/t₀, where L_{c} is the length of the cable and t₀ is the duration, measured on the reflectogram, between the amplitude peak corresponding to the impedance discontinuity at the point of injection and the amplitude peak corresponding to the reflection of the signal from the end of the cable.

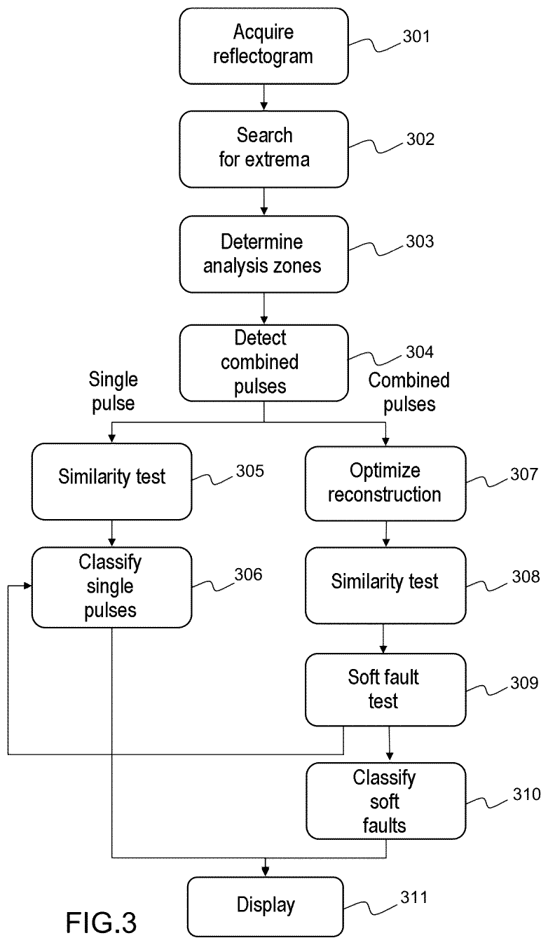

FIG. 3 schematically shows, on a flowchart, the steps for implementing a method for automatically analyzing a reflectogram according to one embodiment.

The method begins in step 301 with the acquisition or reception of a reflectogram measured on a cable to be analyzed using the device and the method described above. In addition to the reflectogram, the method may receive, at input, the sampling period of the signal along with the maximum frequency of the reference signal used to excite the cable.

Optionally, a pre-processing step is applied beforehand to the measured reflectogram in order for example to increase the signal-to-noise ratio through matched filtering.

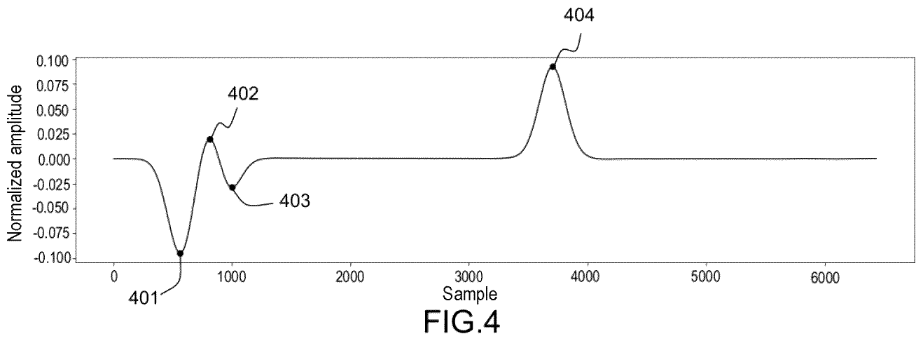

FIG. 4 shows one example of a reflectogram measured for a coaxial cable with a total length of 1 meter and the termination of which corresponds to a load of 50 ohms. A soft fault with a length of 1 cm is located 10 cm from the signal injection port. The excitation signal that is used is a Gaussian-shaped pulse signal with a maximum frequency of 1 GHz.

The above example is given purely by way of illustration in order to explain the operation of the invention, which applies identically to any other reflectogram measured for any type of transmission line.

In step 302, a search for extrema is carried out on the reflectogram. In the example of FIG. 4, the reflectogram comprises four extrema 401, 402, 403, 404.

Step 302 makes it possible to identify the zones of the reflectogram in which there is a high probability of detecting a temporal signature corresponding to an impedance discontinuity on the cable. Step 302 makes it possible to avoid carrying out complete analysis of the reflectogram.

Step 303 then consists in determining analysis zones around the extrema detected in the previous step 302. In other words, step 303 consists in defining a time window around each extremum to which the following steps of the method will be applied.

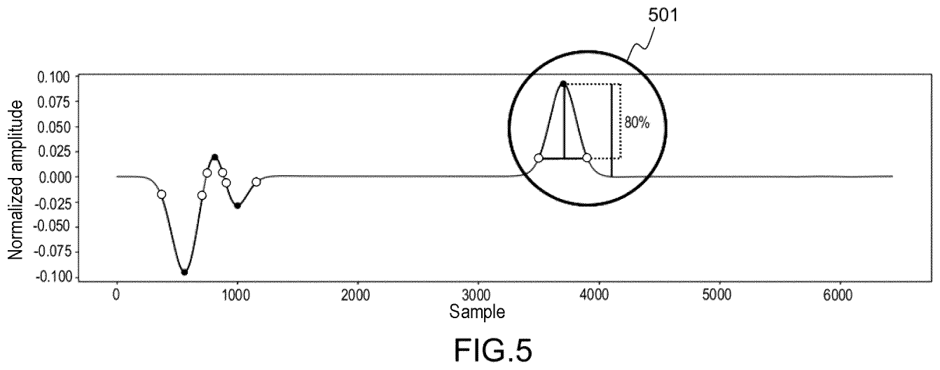

According to one exemplary embodiment, step 303 is carried out by defining the limits of the time window based on computing the width of the pulse at a certain relative height of the prominence of the pulse. In the example of FIG. 5, the analysis zone 501 is determined such that the width of the pulse is measured at 80% of the prominence, that is to say the total height of the pulse measured between the extremum and the base of the pulse. The percentage may be chosen at a different value, but results from a compromise between the desired accuracy and the tolerated false detection rate. A lower percentage leads to lower accuracy, and a higher percentage leads to a risk of false detection after analysis.

Step 303 is for example implemented by way of a prominence computation that consists in determining, on either side of the extremum, the local minima of the signal that define the base of the signal, and then in measuring the prominence equal to the distance between the extremum and the highest local minimum out of the two points that define the base of the signal. The analysis zone is then defined by plotting the width of the pulse at a distance from the extremum equal to 80% of the prominence.

Step 303 is carried out for each pulse associated with an extremum detected in step 302.

Step 304 then consists in analyzing each pulse in its analysis zone in order to determine whether it is a single pulse or a pulse resulting from the combination of multiple other pulses.

Indeed, one of the problems to be solved in order to carry out automatic analysis of a reflectogram concerns pulses that are superimposed and combined because they result from reflections of the signal from impedance discontinuities that are close on the cable or from combination with multiple reflections of the signal. Each pulse detected on the reflectogram thus does not necessarily correspond to a single reflection of the excitation signal, but may often result from a combination of multiple reflections, then making it complex to interpret the temporal signature directly.

Step 304 consists in identifying, for each pulse of the reflectogram, whether it results from a combination of two successive pulses that have a mutual influence on one another by being partially superimposed on one another.

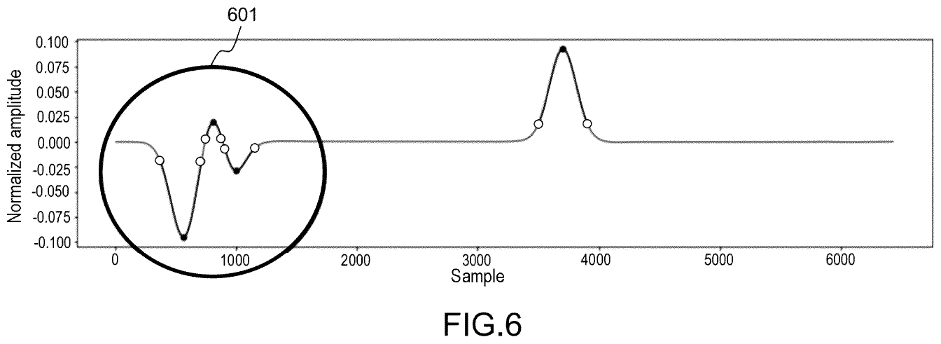

In the example of FIG. 6, zone 601 of the reflectogram corresponds to a superposition of multiple pulses. Indeed, in this example, a soft fault is located at the start of the cable. The Gaussian pulses corresponding to the reflection of the signal from the soft fault are combined with the one corresponding to the impedance mismatch between the measuring apparatus and the cable, at the start of the cable.

This combination implies that the pulses present in zone 601 no longer have the same characteristics as the excitation signal, which is a Gaussian signal in this example. It may be seen in FIG. 6 that the temporal signature of the soft fault differs from that expected because, in general, a soft fault is characterized by two successive Gaussian pulses that are almost identical but are in phase opposition, which is not the case in FIG. 6.

It is thus necessary to determine whether a pulse corresponds to a superposition or a combination of multiple other pulses in order to determine which pulses are at the origin of the potential combination. This is the purpose of step 304 of the analysis method.

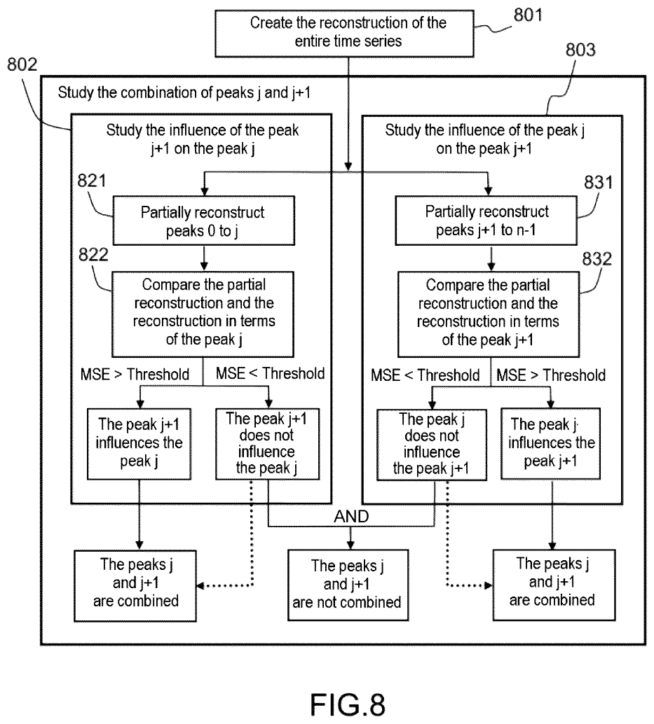

FIG. 8 shows a flowchart of the sub-steps for carrying out step 304 of detecting combined pulses.

Step 801 comprises first determining a total reconstruction of the entire reflectogram in the form of a time series corresponding to the sum of the pulses that have the same position and the same amplitude as the pulses detected on the reflectogram. This reconstructed time series makes it possible to model and simplify the initial reflectogram.

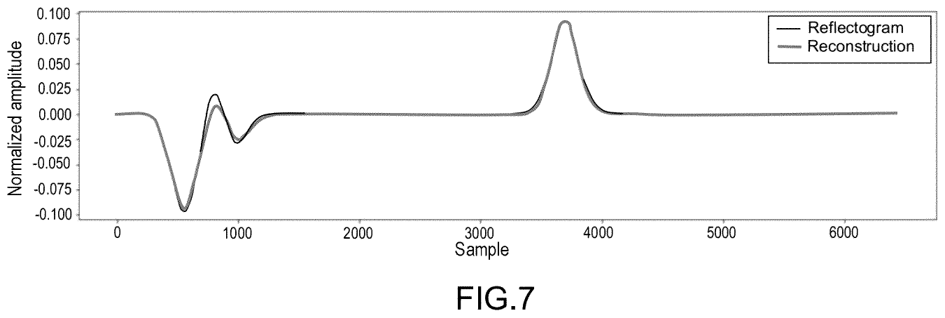

The reconstructed time series is obtained by generating, for each extremum of the reflectogram identified in step 302, a pulse having the same shape as the excitation signal. The example of FIG. 7 shows the reconstructed time series obtained for the reflectogram of FIG. 4.

For this example, the excitation signal is a Gaussian signal, and so each Gaussian pulse of the reconstructed time series is obtained for example using the following formula:

$$A \times {e}^{\frac{- 1}{2} {( \frac{t - b}{a} )}^{2}} .$$

where A is the amplitude of the pulse measured on the reflectogram, that is to say the value of each extremum,

$$a = \frac{1}{f} \times \frac{1}{2 \times \sqrt{2 \times ln ( 2 )}}$$

represents a dilation factor, f is the maximum frequency of the excitation signal,

b is equal to the extremum index multiplied by the sampling period of the signal and represents the temporal translation of the pulse.

The pulse of the reconstructed series is generated using the above formula in the analysis zone determined in step 303.

Without departing from the scope of the invention, the shape of the excitation signal may be different from the Gaussian shape; in this case, the modeling function used to reconstruct the pulses takes into account the shape of the excitation signal.

The algorithm described in FIG. 8 is then applied for each pair of successive pulses of indices j and j+1 identified on the reflectogram.

Step 802 comprises analyzing the potential influence of the pulse of index j+1 on the pulse of index j, and then step 803 comprises performing the reverse operation by analyzing the potential influence of the pulse of index j on the pulse of index j+1.

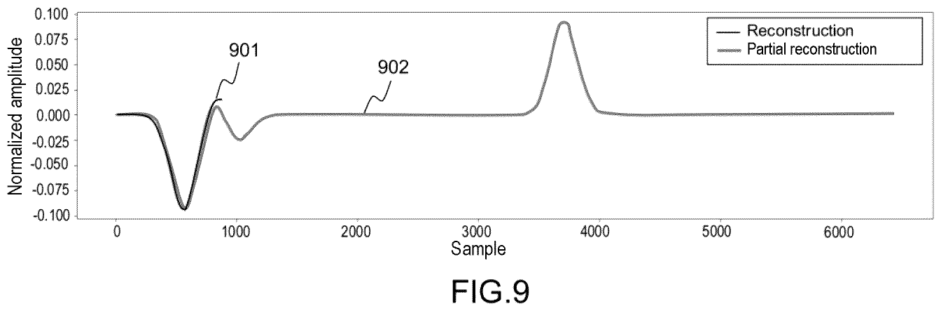

Step 821 comprises constructing a partial reconstruction of the reflectogram corresponding to the sum of the first portion of the pulses from index 0 (first pulse) to index j. This partial reconstruction 901 is shown in the example of FIG. 9 in comparison with the total reconstruction 902. The partial reconstruction makes it possible to simulate a pulse of index j while potentially retaining the influence exerted by previous pulses thereon, but while ignoring the influence of following pulses. The aim is to analyze the pulse of index j in the absence of the influence of the following pulse of index j+1.

It may be seen in FIG. 9 that the two reconstructions 901, 902 differ in terms of the second peak (j=1 for this example).

In step 822, a comparison is carried out between the partial reconstruction 901 and the total reconstruction 902 in the analysis window of the pulse of index j. If the two reconstructions are similar in the analysis zone, this means that the pulse of index j+1 does not influence the pulse of index j, and if not, this means that the pulse of index j+1 has an influence on the pulse of index j.

The comparison between the two reconstructions may be carried out by computing an error criterion between the two reconstructions in the analysis zone, for example a mean-squared error criterion, and then by comparing the result with a predetermined error threshold. This error threshold is for example of the order of 1e-09. Its value is determined according to the application case.

The same processing operations are carried out in step 803 to evaluate the influence of the pulse of index j on the pulse of index j+1. For this purpose, step 831 comprises determining a partial reconstruction of the reflectogram for the pulses ranging from the index j+1 to the index N-1, where N is the number of pulses of the reflectogram .

Step 832 comprises performing a comparison between this partial reconstruction and the total reconstruction in the analysis window of the pulse of index j+1. If the two reconstructions are similar in the analysis zone, this means that the pulse of index j does not influence the pulse of index j+1, and if not, this means that the pulse of index j has an influence on the pulse of index j+1.

Finally, it is concluded that the pulses j and j+1 are combined if at least one of the two pulses influences the other, and if not, these two pulses are not combined.

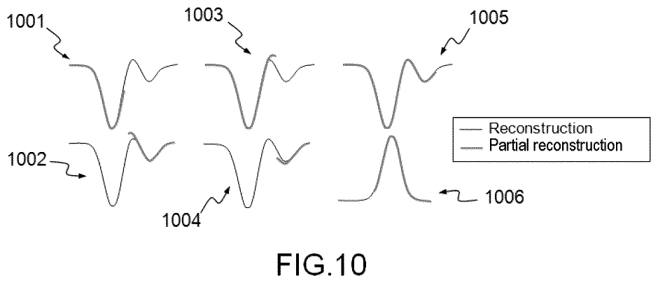

FIG. 10 illustrates the operation of the algorithm of FIG. 8 on an example comprising the four pulses of indices 401, 402, 403, 404 of the reflectogram of FIG. 4.

Diagrams 1001 and 1002 respectively show the comparison of the partial and total reconstructions for the reciprocal influence analysis of the pulses 401, 402. It may be seen that these two pulses are combined since pulse 401 exerts influence on pulse 402 (gap between the two curves in diagram 1002).

Diagrams 1003 and 1004 respectively show the comparison of the partial and total reconstructions for the reciprocal influence analysis of the pulses 402, 403. It may be seen that these two pulses are combined since pulse 402 exerts influence on pulse 403 and vice versa (gap between the two curves in diagram 1003 and diagram 1004).

Diagrams 1005 and 1006 respectively show the comparison of the partial and total reconstructions for the reciprocal influence analysis of the pulses 403, 404. This time, these two pulses are not combined since neither of the two influences the other, as may be seen in the two diagrams 1005 and 1006, which show superimposed curves.

Let us return to the flowchart of FIG. 3. At the end of step 304, it is known, for each pulse of the reflectogram, whether it is a single pulse or a pulse that is combined with another one.

If the pulse is a single pulse, the method moves to step 305 to carry out a similarity test between the pulse of the initial reflectogram and the corresponding pulse of the time series reconstructed in step 801, in the pulse analysis zone. The similarity test is carried out by comparing the two pulses, for example by computing an appropriate error criterion between the two pulses and comparing it with a predetermined error threshold. The error criterion is for example a mean-squared error criterion with a prior step of normalizing, between −1 and 1, the values of the two time series to be compared by dividing them by the extremum of the measured reflectogram. The value of the error threshold is for example of the order of 1e-03, and for example equal to 3.5^{e}-03. Its value is determined according to the application case.

Next, in step 306, the pulse is classified in order to associate it with a type of impedance discontinuity.

If the error criterion is greater than the error threshold, then this means that the portion of the analyzed time series does not have the same shape as the excitation signal, since the reconstructed series is a sum of Gaussian pulses of the same maximum frequency as the excitation signal. In this case, the pulse is not classified in order to avoid a false positive.

Otherwise, a class is assigned to the single pulse according to its temporal abscissa and the value of its extremum. For example, the following classes may be considered. If the normalized amplitude of the extremum is close to −1, the impedance mismatch corresponds to a short circuit. If the normalized amplitude of the extremum is close to 1, the impedance mismatch corresponds to an open circuit. Other classes may be considered, for example a class grouping together characteristic impedances close to those of the cable to be analyzed or a class systematically associating the first impedance discontinuity with the impedance mismatch caused by the difference in impedance between the measurement port and that of the cable.

At this stage, it is not yet possible to identify a soft fault since it is always characterized by a set of two successive peaks in phase opposition.

If a combined pulse is detected in step 304, the method moves to step 307 to determine the position and the amplitude of the pulses at the origin of the combination. For this purpose, an optimization algorithm is implemented in order to obtain an optimized reconstruction from the partial reconstruction of the pulses of a group of combined pulses.

In other words, at the end of step 304, the successive pulses that have been detected as being combined are grouped together, and then an optimization algorithm is applied thereto for the purpose of varying the amplitude and the position of the extrema in order to get as close as possible to the original reflectogram. This thus gives an optimized partial reconstruction in which the amplitudes and the positions of the extrema are modified.

In other words, the positions and amplitudes of the peaks that are at the origin of the combination are sought.

The optimization function that is used seeks to determine the amplitude and position values of each of the peaks of the group that minimize the difference between the original reflectogram and a certain reconstruction that is defined by these values. This function therefore takes, as inputs, the amplitude and the position of each of the peaks of the group along with all the elements needed to compute the difference between the two curves. These elements are the function to be minimized and the series extracted from the reflectogram (portion of the reflectogram defined by the limits of the peaks of the group). Optionally, it is possible to introduce constraints on the amplitude and position values to make solving the optimization more efficient.

The optimization algorithm that is used is for example a trust region reflective algorithm, which is described for example in references [4], [5] and [6].

The optimization step 307 makes it possible notably to refine the accuracy of the temporal positions of the extrema in order subsequently to deduce therefrom an accurate estimate of the position of the faults on the cable.

At the output of step 307, an optimized partial reconstruction is obtained for each group of combined peaks.

In step 308, a similarity test identical to that of step 305 is then carried out, which consists in verifying the similarity between the optimized partial reconstruction and the original reflectogram. To this end, use is made of the same error criterion as in step 305, associated with a different error threshold. The value of the error threshold is for example of the order of 1.5^{e}-03.

If the error criterion is greater than the error threshold, this may mean that the optimization carried out in step 307 is not valid, or else that the analyzed pulses do not have the same shape as the excitation signal. This optimization failure may be due to the fact that some information about contributions of “hidden” pulses may be missing in the pulse sum. In this case, the peaks of the group of combined peaks are not classified.

In the opposite case, in step 309, a test is performed on each successive pair of peaks of the group of peaks to verify whether they correspond to the temporal signature of a soft fault. To this end, it is verified that two successive peaks have substantially the same amplitude and are of opposing signs. If this is the case, the two peaks are grouped together so as to associate them with a soft fault in step 310.

If this is not the case, the method returns to step 306 to classify the single pulses.

The method is carried out for all extrema of the reflectogram. When the entire reflectogram is analyzed, the temporal position of each pulse is converted into a distance corresponding to the position of the fault or of the impedance discontinuity on the cable. This operation is carried out based on the sampling period and the propagation speed of the wave injected into the cable.

Finally, in step 311, the reflectogram is displayed on a user interface with the information associated with the faults and impedance discontinuities that are detected, notably their positions and types associated with the classifications carried out in steps 306 and 310.

The invention may be implemented as a computer program comprising instructions for the execution thereof. The computer program may be recorded on a processor-readable recording medium.

The reference to a computer program that, when it is executed, performs any one of the functions described above is not limited to an application program running on a single host computer. On the contrary, the terms computer program and software are used here in a general sense to refer to any type of computer code (for example application software, firmware, microcode, or any other form of computer instruction) that may be used to program one or more processors to implement aspects of the techniques described here. The computing means or resources may notably be distributed (“Cloud computing”), possibly using peer-to-peer technologies. The software code may be executed on any suitable processor (for example a microprocessor) or processor core or set of processors, be these provided in a single computing device or distributed among multiple computing devices (for example as possibly accessible in the environment of the device). The executable code of each program allowing the programmable device to implement the processes according to the invention may be stored for example in the hard drive or in read-only memory. Generally speaking, the one or more programs will be able to be loaded into one of the storage means of the device before being executed. The central processing unit is able to command and direct the execution of the software code portions or instructions of the one or more programs according to the invention, which instructions are stored in the hard drive or in the read-only memory or else in the other abovementioned storage elements.

The invention may also be implemented in a form embedded in a reflectometry device, as described in FIGS. 1a and 1b. In this case, the device comprises a processing unit such as a computer, personal digital assistant or the like for controlling the reflectometry system and carrying out the method according to the invention and displaying the results produced by the method on a human-machine interface.

### REFERENCES

[1] Salama MEGHRICHE, “Reconnaissance de Forme de Signaux Biologiques” [Pattern Recognition of Biological Signals], thesis, 2008.

[2] Felix Scholkmann, Jens Boss and Martin Wolf, “An Efficient Algorithm for Automatic Peak Detection in Noisy Periodic and Quasi-Periodic Signals”, Algorithms 2012, 5, 588-603.

[3] Samir OUELHA, “Representation et reconnaissance des signaux acoustiques sous-marins” [Representation and recognition of underwater acoustic signals], thesis, 2014.

[4] M. A. Branch, T. F. Coleman, and Y. Li, “A Subspace, Interior, and Conjugate Gradient Method for Large-Scale Bound-Constrained Minimization Problems”, SIAM Journal on Scientific Computing, Vol. 21, Number 1, pp. 1-23, 1999.

[5] J. J. More, “The Levenberg-Marquardt Algorithm: Implementation and Theory”, Numerical Analysis, ed. G. A. Watson, Lecture Notes in Mathematics 630, Springer Verlag, pp. 105-116, 1977.

[6] R. H. Byrd, R. B. Schnabel and G. A. Shultz, “Approximate solution of the trust region problem by minimization over two-dimensional subspaces”, Math. Programming, 40, pp. 247-263, 1988.

1. A method for evaluating a transmission line through reflectometry, comprising the following steps:
obtaining a measurement of the temporal impulse response of a reference signal propagated in the line from a point of injection and then backpropagated to a point of measurement, the temporal measurement, called a reflectogram, comprising a plurality of amplitude peaks each corresponding to an impedance discontinuity,
searching for a set of local extrema in the reflectogram,
determining a total reconstruction of the reflectogram as the sum of pulses each having the shape of the reference signal and the position and the amplitude of said local extrema,
for each pair of successive local extrema of indices j and j+1, comparing the total reconstruction with, respectively, a first partial reconstruction of the reflectogram for the local extrema of indices 0 to j and a second partial reconstruction of the reflectogram for the local extrema of indices j+1 to N-1, N being the number of local extrema, to determine whether or not the pulses of indices j and j+1 of the reflectogram have a mutual influence on one another,
for a group of pulses of the reflectogram that have a mutual influence on one another, determining an optimized reconstruction of the group of pulses from a partial reconstruction of the pulses of the group so as to modify the abscissas of the pulses of the partial reconstruction in order to minimize an error criterion between the optimized partial reconstruction and the measured reflectogram,
comparing the difference between the optimized partial reconstruction and the measured reflectogram with a first error threshold and, if the difference is less than the first error threshold, classifying the impedance discontinuity associated with each pulse of the group of pulses according to its position and its amplitude into the following classes: a soft fault, a short circuit, an open circuit, a load matched to the load of the transmission line, an impedance mismatch between the measurement port and the transmission line.

2. The method for evaluating a transmission line according to claim 1, wherein the shape of the reference signal is a Gaussian pulse.

3. The method for evaluating a transmission line according to claim 1, wherein the step of determining whether or not the pulses of indices j and j+1 of the reflectogram have a mutual influence on one another comprises the following sub-steps:
comparing a first difference between the first partial reconstruction and the total reconstruction with a second error threshold,
comparing a second difference between the second partial reconstruction and the total reconstruction with the second error threshold,
if at least one of the differences out of the first difference or the second difference is greater than the second error threshold, deducing therefrom that the pulses of indices j and j+1 of the reflectogram have a mutual influence on one another, otherwise deducing therefrom that they are independent.

4. The method for evaluating a transmission line according to claim 1, comprising the following step:
for pulses of the reflectogram that are identified as independent, comparing the difference between the reflectogram and the total reconstruction, in a time window surrounding the pulse, with a third error threshold,
if the difference is less than the third error threshold, classifying the impedance mismatch corresponding to the pulse according to its position and its amplitude into the following classes: a short circuit, an open circuit, a load matched to the load of the transmission line, an impedance mismatch between the measurement port and the transmission line.

5. The method for evaluating a transmission line according to claim 1, wherein the optimized reconstruction is obtained by way of a trust region reflective algorithm.

6. The method for evaluating a transmission line according to claim 4, comprising the following step: if the difference between the optimized partial reconstruction and the measured reflectogram is less than the first error threshold for two successive pulses, determining whether the two pulses are of substantially identical amplitudes and of opposing signs and, if so, classifying the impedance mismatch corresponding to these two pulses as resulting from a soft fault, and if not, classifying the impedance mismatch corresponding to each of the two pulses according to its position and its amplitude into the following classes: a short circuit, an open circuit, a load matched to the load of the transmission line, an impedance mismatch between the measurement port and the transmission line.

7. The method for evaluating a transmission line according to claim 1, furthermore comprising a step of extracting each pulse associated with an extremum of the reflectogram, within a time interval of width chosen such that the distance between the apex of the pulse and said width is equal to a predetermined percentage, for example at least equal to 80%, of the total height of the pulse.

8. The method for evaluating a transmission line according to claim 1, wherein the measured reflectogram is amplitude-normalized between −1 and 1.

9. The method for evaluating a transmission line according to claim 1, wherein, before the comparison with the first error threshold or the third error threshold, the reflectogram and the optimized or total partial reconstruction are normalized with respect to the extremum of the reflectogram.

10. The method for evaluating a transmission line according to claim 1, furthermore comprising a step of determining the positions of the impedance discontinuities from the temporal abscissas of the extrema of the reflectogram and a step of displaying the positions and types of the impedance discontinuities on a human-machine interface.

11. A computer program comprising instructions for carrying out the method according to claim 1 when the program is executed by a processor.

12. A processor-readable recording medium on which there is recorded a program comprising instructions for carrying out the method according to claim 1 when the program is executed by a processor.
